(19) United States
(12) Patent Application Publication
(10) Pub. No.: US 2012/0126341 A1
(43) Pub. Date: May 24, 2012

(54) USING LOW PRESSURE EPI TO ENABLE LOW RDSON FET

(75) Inventors: Gregory Dix, Tempe, AZ (US); Pam Leatherwood, Tempe, AZ (US)

(73) Assignee: Microchip Technology Incorporated

(21) Appl. No.: 13/291,515

(22) Filed: Nov. 8, 2011

Related U.S. Application Data
(60) Provisional application No. 61/416,410, filed on Nov. 23, 2010.

(51) Int. Cl. H01L 29/78; H01L 21/20

(52) U.S. Cl. 257/402; 438/492; 257/E29.255; 257/E21.09

(57) ABSTRACT

A method for forming an epitaxial layer on a substrate may have the steps of: forming a heavily doped silicon substrate; depositing an epitaxial layer at sub atmospheric pressure on the heavily doped silicon substrate; and implanting dopant into the epitaxial layer by ion implantation to form a lightly doped epitaxial layer.

### CROSS-REFERENCE TO RELATED APPLICATIONS

This application claims the benefit of U.S. Provisional Application No. 61/416,410 filed on Nov. 23, 2010, entitled “USING LOW PRESSURE EPI TO ENABLE LOW RDSON FET”, which is incorporated herein in its entirety.

### TECHNICAL FIELD

The present disclosure relates to fabrication of semiconductor devices, in particular, the formation of a shallow epitaxial silicon (Epi) layer on a silicon substrate.

### BACKGROUND

In particular, in the fabrication of field effect transistors (FETs) for power applications whether used in integrated semiconductor devices or discrete semiconductor devices, a low on resistance of such a device is generally desired. When designing a vertical power transistor, generally, the substrate serves as a drain and a load current flows through the substrate to the drain contact. Hence, the substrate is required to have a low resistance for such devices. The formation of a low RdsOn vertical-current-flow FET requires the use of a highly doped substrate in order to minimize the series resistance to the wafer backside. However, the doping levels required to achieve this are far too high to create a device with adequate breakdown voltage. The conventional growth of an epitaxial silicon (Epi) layer in a silicon substrate is achieved under atmospheric pressure which results in a gradual transition between the highly doped substrate and the lightly doped Epi-layer suitable for power FET device formation. In addition the concentration of dopant in the Epi generally is not tightly controlled. A relatively large Epi-layer thickness is thus required to obtain a light enough background concentration which again increases the series resistance, thereby limiting performance of the power FET device.

### SUMMARY

Therefore, a need exists for a high power field effect transistor (FET) device having high breakdown voltage and low R_{dsOn}.

According to an embodiment, a method for forming an epitaxial layer on a substrate, may comprise the steps of forming a heavily doped silicon substrate; depositing an epitaxial layer at sub atmospheric pressure on the heavily doped silicon substrate; and implanting dopant into the epitaxial layer by ion implantation to form a lightly doped epitaxial layer.

According to a further embodiment, the epitaxial layer may have a thickness of about 1.0 to 2.0 microns. According to a further embodiment, the epitaxial layer may have a thickness of about 1.5 to 2.0 microns. According to a further embodiment, the method may further comprise the step of implanting and annealing the silicon substrate and lightly doped epitaxial layer. According to a further embodiment, the method may further comprise forming a high breakdown voltage power field effect transistor (FET) in said epitaxial layer, wherein the doping of the substrate and the thickness and doping of the epitaxial layer provide for a low on-resistance of the power FET. According to a further embodiment, the epitaxial layer can be lightly doped. According to a further embodiment, no dopant may be added for depositing the epitaxial layer. According to a further embodiment, the substrate can be doped with a concentration of about 10⁺¹⁹-10⁺²⁰. According to a further embodiment, the low pressure can be up to 50,000 (fifty thousand) Pa. According to a further embodiment, the low pressure can be 2660 Pa.

According to another embodiment, a semiconductor device may comprise a heavily doped silicon substrate; an epitaxial layer deposited at sub atmospheric pressure on the heavily doped silicon substrate, wherein dopant is implanted into the epitaxial layer by ion implantation to form a lightly doped epitaxial layer.

According to a further embodiment of the semiconductor device, the epitaxial layer may have a thickness of about 1.0 to 2.0 microns. According to a further embodiment of the semiconductor device, the epitaxial layer may have a thickness of about 1.5 to 2.0 microns. According to a further embodiment of the semiconductor device, the silicon substrate and lightly doped epitaxial layer can be implanted and annealed. According to a further embodiment of the semiconductor device, a high breakdown voltage power field effect transistor (FET) can be formed in said epitaxial layer, wherein the doping of the substrate and the thickness and doping of the epitaxial layer provide for a low on-resistance of the power FET. According to a further embodiment of the semiconductor device, the epitaxial layer can be lightly doped. According to a further embodiment of the semiconductor device, no dopant can be added for the deposited epitaxial layer. According to a further embodiment of the semiconductor device, the substrate can be doped with a concentration of about 10⁺¹⁹-10⁺²⁰ . According to a further embodiment of the semiconductor device, the sub atmospheric pressure can be up to 50,000 (fifty thousand) Pa. According to a further embodiment of the semiconductor device, the sub atmospheric pressure can be 2660 Pa.

### BRIEF DESCRIPTION OF THE DRAWINGS

FIG. 1 shows an exemplary embodiment of a substrate and Epi-layer.

FIG. 2 shows a transistor cell formed in a structure according to FIG. 1.

FIG. 3 shows a graph showing a comparison of Epi depositions using standard pressure Epi and low pressure Epi.

FIG. 4 shows a graph of the low pressure Epi deposition after Ion implantation, and anneal of FIG. 1.

### DETAILED DESCRIPTION

According to the teachings of this disclosure, a different approach in forming the Epi-layer is used. According to various embodiments, a highly doped substrate serves as a base material. Then, a low pressure, in particular sub atmospheric pressure Epitaxial silicon (Epi) deposition, for example a deposition of the Epi-layer at a pressure of 2660 (two thousand six hundred sixty) Pa, is performed. Preferably, the sub-atmospheric pressure can be up to ½ atmospheric pressure, for example up to 50,000 (fifty thousand) Pa. According to other embodiments, other sub-atmospheric pressures can be used. According to various embodiments, the Epi deposition may have a very low, or no dopant present. This results in a lightly doped and relatively shallow deposition of an Epi layer on the highly (heavily) doped silicon (Si) substrate. According to various embodiments, the sub atmospheric pressure Epi deposition allows maintaining a sharp transition between the lightly doped shallow Epi-layer and the highly doped Si substrate. By using a sub atmospheric pressure Epi-layer deposition, according to an embodiment, the thickness of the Epi-layer can be preferably reduced to about 1.5-2.0 microns. However, according to other embodiments, a reduction to about 1.0-2.0 microns is also possible. In addition, precise control of the shallow Epi-layer's lightly doped concentration can be realized by the use of ion implantation. This well controlled shallow layer doping concentration allows a reduction in the depth of the low concentration area, thus reducing parasitic substrate resistance that is suitable for creating a high power FET device having high breakdown voltage and low R_{dsOn}.

Advantages of the invention disclosed herein are for example but not limited to: 1) fabrication of a high breakdown voltage power FET having a low RdsOn, 2) a higher performance power FET resulting from improved RdsOn characteristics, 3) less variation of parameters of power FET devices through better process control, and 4) reduction of manufacturing costs by the elimination of complex fabrication steps that were previously required to link the drain to the substrate.

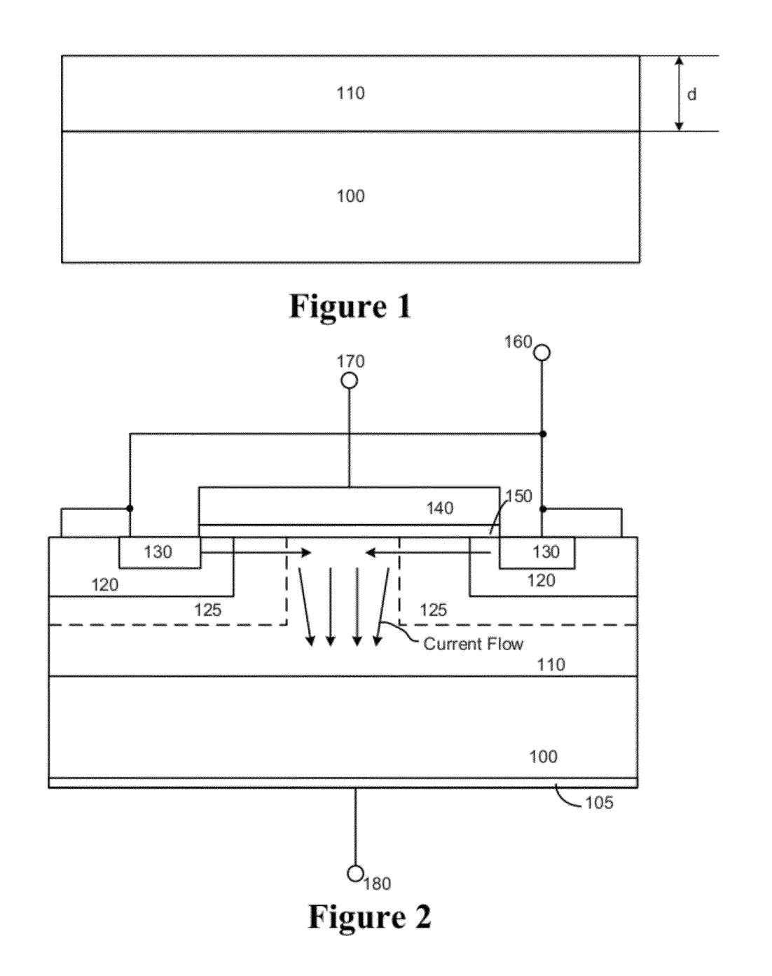

FIG. 1 shows a heavily doped substrate 100 onto which an Epi-layer 110 is deposited under sub atmospheric pressure, for example, a pressure of 2660 Pa. As mentioned above, the pressure may be preferably below 50,000 Pa. According to other embodiments other sub-atmospheric pressures may be used. Depositing the Epi-layer 110 in a sub atmospheric pressure environment allows for a significant reduction of the Epi-layer thickness d to values of 1.0-2.0 microns, preferably 1.5-2.0 microns. After deposition of the Epi-layer 110, the Epi layer 110 is doped using ion implantation typically to a value of, for example, between 10⁺¹⁵-10⁺¹⁶. For example, Phosphorus, Antimony or Arsenic may be used for ion implantation. However, other suitable dopants may be used. This allows for a well defined control of the concentration as explained above. After ion implantation, the layer can be annealed. Such a structure can then be used to form vertical transistor cells as for example shown in FIG. 2.

FIG. 2 shows an N⁺⁺ substrate 100 on which a N⁻ doped Epi-layer 110 is formed according to the above described process. The thickness and doping of the Epi-layer 110 generally determines the voltage rating of the device. Because of the fact that the doping can be well controlled, precise voltage ratings can be achieved. From the top into the Epi-layer 110 there are formed N⁺ doped left and right source regions 130 surrounded by P-doped region 120 which forms the P-base surrounded by its out diffusion area 125. A source contact 160 generally contacts both regions 130 and 120 on the surface of the die and is generally formed by a metal layer that connects both left and right source region. An insulating layer 150, typically silicon dioxide or any other suitable material, insulates a gate 140 which covers a part of the P-base region 120 and out diffusion area 125. The gate can be formed with polysilicon, amorphous silicon or any other suitable conductive material. The gate 140 is connected to a gate contact 170 which is usually formed by another metal layer. The bottom side of this vertical transistor has another metal layer 105 forming the drain contact 180. In summary, FIG. 2 shows a typical elementary cell of a MOS-FET that can be very small and comprises a common drain, a common gate and two source regions and two channels. Other cell structures can be formed in the Epi-layer according to various embodiments to be used in a vertical power MOS-FET. A plurality of such cells may generally be connected in parallel to form a power MOS-FET.

In the On-state, a channel is formed within the area of regions 120 and 125 covered by the gate reaching from the surface into the regions 120 and 125, respectively. Thus, current can flow as indicated by the horizontal arrow. This particular cell structure must provide for a sufficient width of gate 140 to allow for this current to turn into a vertical current flowing to the drain side as indicated by the vertical arrows.

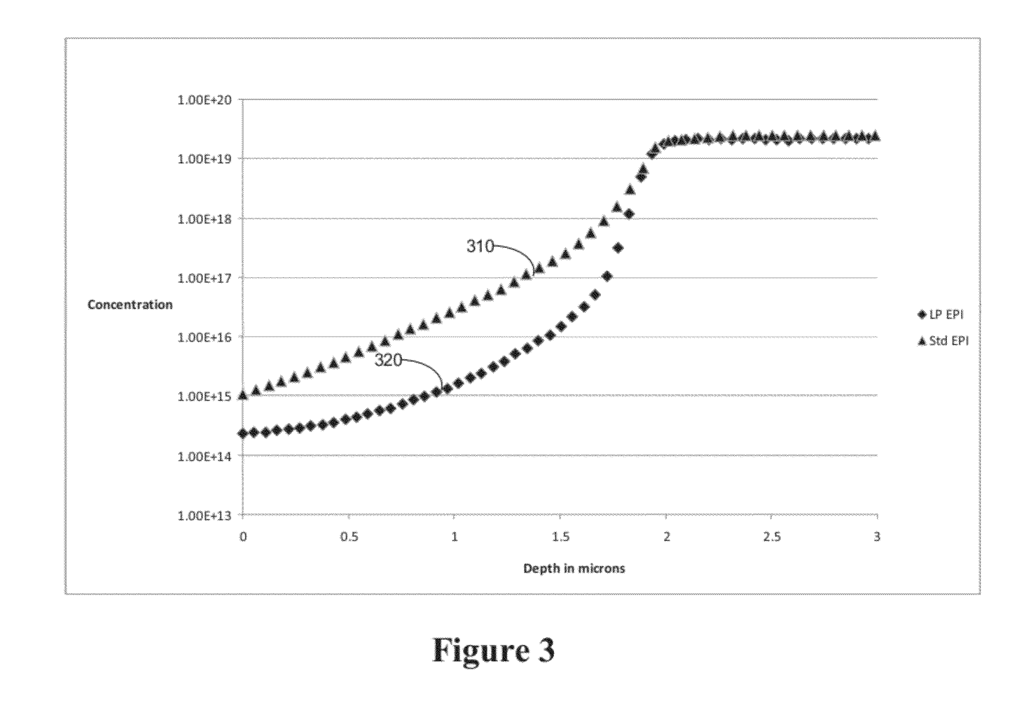

FIG. 3 shows a comparison of conventional Epi-layers and the improved Epi-layer according to various embodiments. The x-axis shows the depth from the surface into the Epi-layer 110 and into substrate 100. The y-axis designates the dopant concentration. The triangle marked curve 310 designates a conventional Epi-layer whereas the diamonds marked curve 320 designates an Epi-layer according to various embodiments. As can be seen, the various embodiments allow for much lower dopant concentration in the Epi-layer and a higher doped substrate while maintaining a gradual transition towards the substrate which starts at about 2 microns. As shown in FIG. 3, the conventional Epi-layer and the low pressure (LP) Epi-layer are both intrinsic (no dopant). The LP Epi deposition shows significant reduction in up diffusion of the substrate dopant.

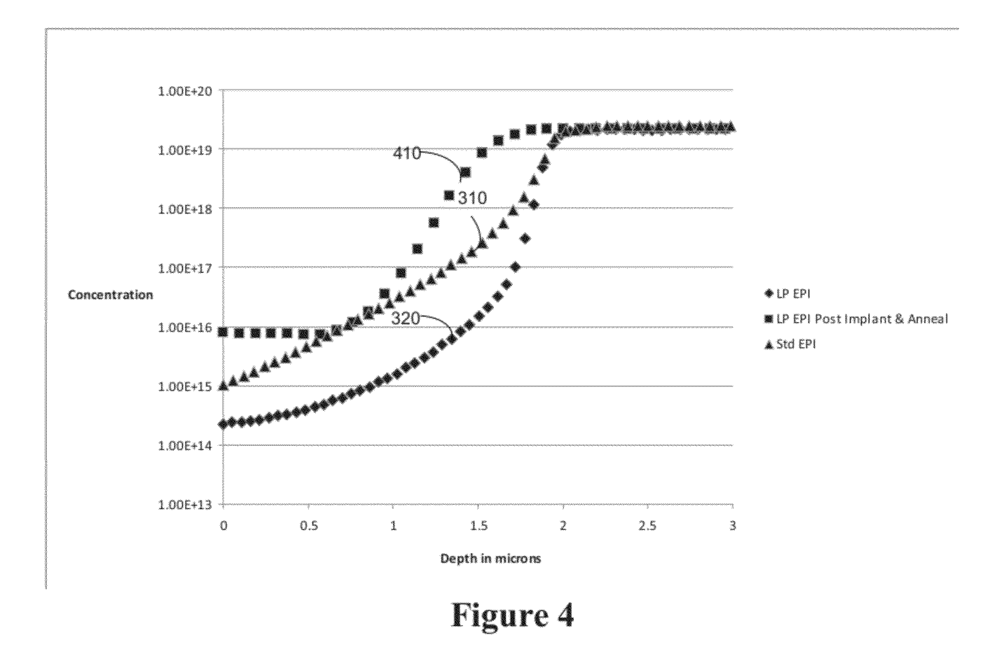

FIG. 4 shows the resulting dopant concentration after implantation and annealing has been performed. Triangle and diamond marked curves 310, 320 correspond to those shown in FIG. 3. The square marked curve 410 shows the LP Epi-layer after implantation and annealing.

While embodiments of this disclosure have been depicted, described, and are defined by reference to example embodiments of the disclosure, such references do not imply a limitation on the disclosure, and no such limitation is to be inferred. The subject matter disclosed is capable of considerable modification, alteration, and equivalents in form and function, as will occur to those ordinarily skilled in the pertinent art and having the benefit of this disclosure. The depicted and described embodiments of this disclosure are examples only, and are not exhaustive of the scope of the disclosure.

What is claimed is:

1. A method for forming an epitaxial layer on a substrate, said method comprising the steps of:
forming a heavily doped silicon substrate;
depositing an epitaxial layer at sub atmospheric pressure on the heavily doped silicon substrate; and
implanting dopant into the epitaxial layer by ion implantation to form a lightly doped epitaxial layer.

2. The method according to claim 1, wherein the epitaxial layer has a thickness of about 1.0 to 2.0 microns.

3. The method according to claim 1, wherein the epitaxial layer has a thickness of about 1.5 to 2.0 microns.

4. The method according to claim 1, further comprising the step of Implanting and annealing the silicon substrate and lightly doped epitaxial layer.

5. The method according to claim 4, further comprising:
forming a high breakdown voltage power field effect transistor (FET) in said epitaxial layer, wherein the doping of the substrate and the thickness and doping of the epitaxial layer provide for a low on-resistance of the power FET.

6. The method according to claim 1, wherein the epitaxial layer is lightly doped.

7. The method according to claim 6, wherein no dopant is added for depositing the epitaxial layer.

8. The method according to claim 1, wherein the substrate is doped with a concentration of about 10⁺¹⁹-10⁺²⁰ .

9. The method according to claim 1, wherein the low pressure is up to 50,000 (fifty thousand) Pa.

10. The method according to claim 9, wherein the low pressure is 2660 Pa.

11. A semiconductor device comprising:
a heavily doped silicon substrate;
an epitaxial layer deposited at sub atmospheric pressure on the heavily doped silicon substrate, wherein dopant is implanted into the epitaxial layer by ion implantation to form a lightly doped epitaxial layer.

12. The semiconductor device according to claim 11, wherein the epitaxial layer has a thickness of about 1.0 to 2.0 microns.

13. The semiconductor device according to claim 11, wherein the epitaxial layer has a thickness of about 1.5 to 2.0 microns.

14. The semiconductor device according to claim 11, wherein the silicon substrate and lightly doped epitaxial layer are implanted and annealed.

15. The semiconductor device according to claim 14, wherein a high breakdown voltage power field effect transistor (FET) is formed in said epitaxial layer, wherein the doping of the substrate and the thickness and doping of the epitaxial layer provide for a low on-resistance of the power FET.

16. The semiconductor device according to claim 11, wherein the epitaxial layer is lightly doped.

17. The semiconductor device according to claim 16, wherein no dopant is added for the deposited epitaxial layer.

18. The semiconductor device according to claim 11, wherein the substrate is doped with a concentration of about 10⁺¹⁹-10⁺²⁰ .

19. The semiconductor device according to claim 11, wherein the sub atmospheric pressure is up to 50,000 (fifty thousand) Pa.

20. The semiconductor device according to claim 19, wherein the sub atmospheric pressure is 2660 Pa.
